(19) United States
(12) Patent Application Publication
(10) Pub. No.: US 2003/0026991 A1
(43) Pub. Date: Feb. 6, 2003

(54) Passive electrical components formed on carbon coated insulating substrates

(75) Inventors: Rajendra Shah, Marlton, NJ (US); Joseph B. Mazzochette, Cherry Hill, NJ (US); Martin A. Helfand, Cherry Hill, NJ (US)

Correspondence Address: PENNIE & EDMONDS LLP, 1155 Avenue of Americas, New York, NY, 10036-2711, US

(73) Assignee: EMC TECHNOLOGY, INC.

(21) Appl. No.: 10/219,215

(22) Filed: Aug. 13, 2002

Related U.S. Application Data
(62) Division of application No. 09/638,539, filed on Aug. 10, 2000, now abandoned.
(60) Provisional application No. 60/147,997, filed on Aug. 10, 1999.

(51) Int. Cl. B32B 9/00

(52) U.S. Cl. 428/408; 428/336; 428/698; 428/701

(57) ABSTRACT

A substrate having a diamond or diamond-like carbon coating of at least one micron thickness on an underlayer of an insulating material such as AlN. Such a substrate is advantageously used as a mounting for passive electrical components such as microwave and radio-frequency (rf) resistors, capacitors, attenuators, terminators and loads.

### FIELD OF THE INVENTION

This relates to passive electrical components formed on carbon coated insulating substrates.

### BACKGROUND OF THE INVENTION

Passive components such as resistors, capacitors attenuators, terminations and loads are commonly built on insulating substrates that have high electrical resistivity and high thermal conductance. Such substrates typically are composed of a thin sheet of sintered ceramic material such as beryllium oxide (BeO), aluminum oxide (A₂O₃, magnesium oxide (MgO), boron nitride (BN), aluminum nitride (AlN) or silicon carbide (SiC). Substrates made from ternary compounds, such as MgSiN₂, are also known.

Use of these substrates involves a variety of tradeoffs. For example, while BeO has a high thermal conductivity (2.5 W/cm° C. at 25° C.), low dielectric constant (6.6 @ 1MHz) and high electrical resistivity (10¹⁵ ohm−cm), beryllium is toxic. Al₂O₃ and MgO have relatively low thermal conductance. AlN has nearly the same thermal conductivity and electrical resistivity as BeO but a higher dielectric constant.

### SUMMARY OF THE INVENTION

We have found that a diamond or diamond-like carbon coating of at least one micron thickness on an underlayer of an insulating material such as AlN provides a substrate having thermal conductivity and dielectric properties superior to AlN alone.

Further, we have found that such a substrate is advantageously used as a mounting for passive electrical components such as microwave and radio-frequency (rf) resistors, capacitors, attenuators, terminators and loads. The addition of the diamond layer on the surface of the underlayer serves to rapidly spread the heat generated from a material or a point source constructed on the diamond layer. The rapid heat spreading is an advantage because the size and cost of the component may be reduced while the performance is improved. The reduction in dielectric constant is also advantageous.

### DETAILED DESCRIPTION OF THE PREFERRED EMBODIMENT OF INVENTION

These and other objects, features and advantages of our invention will be more readily apparent from the following detailed description of a preferred embodiment of the invention.

As shown in a cross-sectional view in the drawing, a continuous diamond (or diamond-like) carbon layer 30 is formed on an underlayer 20 of a sheet of an insulating material. The carbon layer illustratively is about 1-1000 microns in thickness and preferably is about 100 microns in thickness. The underlayer may have any thickness but typically is about 0.25 to 1.5 millimeters (mm.) (0.01 to 0.06 inches) in thickness. Preferably it is about 1 mm. (0.04 inches) microns in thickness.

Underlayer 20 may be made of any insulating material that can be formed in a thin sheet and has satisfactory strength. Typical such materials are the binary compounds BeO, Al₂O₃, MgO, SiC, BN and AlN, of which AlN is preferred. Other materials may also be used.

Layer 30 is a carbon layer that is formed on underlayer 20 so that it has a diamond-like structure. Different methods may be used. Preferably, layer 30 is formed by hot filament chemical vapor deposition (CVD) in which methane (CH₄) gas is decomposed at high temperatures on the order of 1000° C. Alternatively, reactive radio frequency sputtering, molecular CVD, low pressure CVD, physical vapor deposition, hot pressed diamond composite and bulk diamond may also be used to form layer 30. Details concerning the formation of diamond and diamond-like films and coatings are set forth in the following publications which are incorporated herein by reference: U.S. Pat. No. 5,628,824; Diamond and Diamond-Like Films and Coatings, edited by Clausing et al. (Plenum, New York), pp. 678-701; 829-853; The Properties of Natural and Synthetic Diamond, edited by Field, (Acadamic, London), pp. 35-80, 405, 445-467, 687-698; Synthetic Diamond. Emerging CVD Science and Technology, edited by Spear and Dismukes, (Wiley, New York), pp. 317-319, 627-649.

The carbon layer 30 that is formed need not be and normally will not be a monocrystalline diamond. Substantial impurities can be present in the carbon layer without having significant effect on the desired thermal conductivity and electrical resistivity. In general, an acceptable layer will have a thermal conductivity in the range from 2.5 to 12 W/cm° C., and an electrical resistivity in the range from 10¹⁰ 10¹⁶ ohm·cm. constant for the layer should be in the range from 1 to 20.

For the case of a substrate having a diamond-like carbon layer 30 in the range of about 1-1000 microns in thickness on an AlN underlayer 20, Table I sets forth a comparison of the electrical properties of the diamond layer with that of substrates made only of BeO or AlN.

TABLE 1

| Material | BeO | AlN | Diamond |
|---|---|---|---|
| Thermal Conductivity | 2.5 | 1.7 | 9-12 |
| (W/cm° C. at 25° C.) | | | |
| Dielectric Constant @ | 6.6 | 8.5 | 5.7 |
| 1 MHz | | | |
| Electrical Resistivity | 10¹⁵ | 10¹⁴ | 10¹⁵ |
| (ohm-cm) | | | |

Passive components 40 may be formed on layer 30 using any of the techniques conventionally used in the art. As suggested by structures 42 and 44, a variety of different structures may be formed on the same substrate. In particular, both thin film and thick film structures of resistors, capacitors, attenuators, terminations and loads may be formed on the substrate. Such components are particularly useful as microwave and radio frequency components.

Different materials may be used in the formation of the passive components. A preferred material is tantalum nitride (TaN) and methods for the formation of resistors, capacitors, attenuators, terminations and loads using TaN are well known in the art. Alternative materials are a fritted metal oxide, nickel-chromium or carbon film.

In use, underlayer 20 is typically mounted on a heat sink (not shown), which is used to conduct heat away from the underlayer.

As will be apparent to those skilled in the art, numerous modifications may be made in the above-described embodiment that are within the spirit and scope of the invention.

What is claimed is:

1. A substrate for electrical components comprising:
an insulating layer having at least a first surface; and
a carbon layer on the first surface.

2. The substrate of claim 1 wherein the carbon layer is diamond.

3. The substrate of claim 1 wherein the carbon layer is diamond-like.

4. The substrate of claim 1 wherein the carbon layer has a thermal conductivity in the range from 2.5 to 12 W/cm° C. and an electrical resistivity in the range from 10¹⁰ to 10¹⁶ ohm·cm.

5. The substrate of claim 1 wherein the carbon layer is between about 1 to 1000 microns thick.

6. The substrate of claim 1 wherein the carbon layer is formed by chemical vapor deposition on the ensulating layer.

7. The substrate of claim 1 wherein the carbon layer is formed by hot filament chemical vapor deposition in which methane gas is decomposed.

8. The substrate of claim 1 wherein the insulating layer is made of BeO, Al₂O₃, MgO, BN, AlN or SiC.

9. A circuit comprising:
an insulating layer having at least a first surface;
a carbon layer on the first surface; and
at least one component formed on the carbon layer.

10. The circuit of claim 9 wherein the carbon layer is diamond.

11. The circuit of claim 9 wherein the carbon layer is diamond-like.

12. The circuit of claim 9 wherein the carbon layer has a thermal conductivity in the range from 2.5 to 12 W/cm° C. and an electrical resistivity in the range from 10¹⁰ to 10¹⁶ ohm·cm.

13. The circuit as set forth in claim 9 wherein the carbon layer is between about 1 to 1000 microns thick.

14. The circuit of claim 9 wherein the carbon layer is formed by chemical vapor deposition on the insulating layer.

15. The circuit of claim 9 wherein the carbon layer is formed by hot filament chemical vapor deposition in which methane gas is decomposed.

16. The circuit of claim 9 wherein the insulating layer is made of BeO, Al₂O₃, MgO, BN, AlN or SiC.

17. The circuit as set forth in claim 9 wherein the component is a thin film component.

18. The circuit as set forth in claim 9 wherein the component is a thick film component.

19. A method of forming a passive electrical component comprising the steps of:
providing an electrically insulating underlayer;
forming on the underlayer a carbon layer; and
forming at least one of a resistor, a capacitor, an attenuator, a termination or a load on the carbon layer.

20. The method of claim 19 wherein the carbon layer has thermal conductivity in the range from 2.5 to 12 W/cm° C. and an electrical resistivity in the range from 10¹⁰ to 10¹⁶ ohm·cm.
